(19) United States
(12) Patent Application Publication
(10) Pub. No.: US 2026/0136498 A1
(43) Pub. Date: May 14, 2026

(54) PHASE-CHANGE COOLING SYSTEMS WITH ELECTROMAGNETICALLY INDUCED FLOW

(71) Applicant: Raytheon Company, Arlington, VA (US)

(72) Inventors: James Demetrios Saraidaridis, South Glastonbury, CT (US); Yasmin Khakpour, South Windsor, CT (US); Abbas A. Alahyari, Glastonbury, CT (US); Hamid Reza Ghazizadeh Karani, Scituate, RI (US)

(21) Appl. No.: 19/373,249

(22) Filed: Oct. 29, 2025

Related U.S. Application Data
(60) Provisional application No. 63/719,208, filed on Nov. 12, 2024.

(51) Int. Cl. H05K 7/20; H02P 13/00

(52) U.S. Cl. CPC H05K 7/20327; H02P 13/00; H05K 7/20381

(57) ABSTRACT

Thermal management systems and methods of operation include a phase-change element including a phase-change material configured to change in phase state as the phase-change material absorbs heat and a plurality of active particles arranged within the phase-change material, with the plurality of active particles configured to induce a motion of the phase-change material when subjected to an applied electromagnetic field.

### CROSS-REFERENCE TO RELATED APPLICATIONS

This application claims the benefit of priority to U.S. Application No. 63/719,208 filed November 12, 2024, the disclosure of which is incorporated herein by reference in its entirety.

### BACKGROUND

The subject matter disclosed herein generally relates to heat removal and cooling systems for use with electronic devices, and, more particularly, to improved cooling schemes using phase-change materials and electromagnetically induced flow of working fluids.

A characteristic property of phase-change materials (PCMs) is that PCMs have a high latent heat of fusion. This allows PCMs to store a large amount of energy with a low temperature increase. As such, PCMs tend to be a solution to certain challenges in dynamic thermal management. However, another characteristic property of PCMs is that the power density tends to decrease as a transient melt front moves away from a heat source. In operation, PCM used for the transient thermal management is initially in a solid state. As heat is transferred from the heat source to the PCM, the temperature of the solid PCM increases due to absorption of heat and starts to melt. The melting (or phase change) occurs when the melting point of the PCM is reached due to heat pickup or heat transfer from the heat source. During the phase change, the PCM temperature will remain relatively constant as heat absorbed is stored as latent heat until all solid portions of the PCM becomes completely liquid. Improving control of the melt-front may provide increased thermal efficiencies and/or thermal performance and may providing improved cooling and/or operation of thermal management systems.

### SUMMARY

According to some embodiments, thermal management systems are provided. The thermal management systems include a phase-change element comprising a phase-change material configured to change in phase state as the phase-change material absorbs heat and a plurality of active particles arranged within the phase-change material, the plurality of active particles configured to induce a motion of the phase-change material when subjected to an applied electromagnetic field.

In addition to one or more of the features described herein, or as an alternative, further embodiments of the thermal management systems may include a field generator arranged in proximity to the phase-change element and configured to selectively apply an electromagnetic field to the phase-change element and induce motion of the plurality of active particles.

In addition to one or more of the features described herein, or as an alternative, further embodiments of the thermal management systems may include a controller arranged to control operation of the field generator.

In addition to one or more of the features described herein, or as an alternative, further embodiments of the thermal management systems may include a sensor arranged to monitor a thermal condition at an interface between the phase-change element and a heat load, wherein the controller is configured to cause the field generator to generate the field in response to the thermal condition at the interface.

In addition to one or more of the features described herein, or as an alternative, further embodiments of the thermal management systems may include a heat load.

In addition to one or more of the features described herein, or as an alternative, further embodiments of the thermal management systems may include that the plurality of active particles comprise charged particles.

In addition to one or more of the features described herein, or as an alternative, further embodiments of the thermal management systems may include a field generator arranged proximate the phase-change element and configured to generate an electric field.

In addition to one or more of the features described herein, or as an alternative, further embodiments of the thermal management systems may include that the field generator comprises a first electrode arranged on a first side of the phase-change element and a second electrode arranged on a second side of the phase-change element opposite the first electrode.

In addition to one or more of the features described herein, or as an alternative, further embodiments of the thermal management systems may include that the field generator comprises a first electrode pair arranged to generate a first field in a first orientation and a second electrode pair arranged to generate a second field in a second orientation that is different from the first orientation.

In addition to one or more of the features described herein, or as an alternative, further embodiments of the thermal management systems may include that the plurality of active particles comprise magnetic particles.

In addition to one or more of the features described herein, or as an alternative, further embodiments of the thermal management systems may include a field generator arranged proximate the phase-change element and configured to generate a magnetic field.

In addition to one or more of the features described herein, or as an alternative, further embodiments of the thermal management systems may include that the plurality of active particles comprise non-magnetic beads coated with a magnetic material.

In addition to one or more of the features described herein, or as an alternative, further embodiments of the thermal management systems may include that the phase-change element comprises a housing, wherein the phase-change materials is contained within the housing and the housing further defines a void space defining a path for flow of the phase-change material to travel during application of the applied electromagnetic field.

In addition to one or more of the features described herein, or as an alternative, further embodiments of the thermal management systems may include that the plurality of active particles are fixed in position within the phase-change element, and application of the applied electromagnetic field to the plurality of active particles causes the plurality of active particles to rotate in place to induce a flow of the phase-change material.

In addition to one or more of the features described herein, or as an alternative, further embodiments of the thermal management systems may include that the plurality of active particles are embedded within the phase-change material and application of the applied electromagnetic field induces the plurality of active particles to move within the phase-change element and cause a flow of phase-change material.

According to some embodiments, methods of removing heat from a heat load are provided. The methods include arranging a phase-change element in thermal contact with a heat load, wherein the phase-change element comprises a phase-change material having a plurality of active particles arranged within the phase-change material, the plurality of active particles configured to induce a motion of the phase-change material when subjected to an applied electromagnetic field and applying an electromagnetic field to the phase-change element to induce a motion of the plurality of active particles and cause motion of the phase-change material.

In addition to one or more of the features described herein, or as an alternative, further embodiments of the methods may include that the electromagnetic field is an applied magnetic field.

In addition to one or more of the features described herein, or as an alternative, further embodiments of the methods may include that the electromagnetic field is an applied electric field.

In addition to one or more of the features described herein, or as an alternative, further embodiments of the methods may include monitoring a thermal condition at an interface between the phase-change element and the heat load and applying the field in response to the thermal condition.

In addition to one or more of the features described herein, or as an alternative, further embodiments of the methods may include that applying the field comprises applying a first field at a first orientation to induce a first motion of the phase-change material and applying a second field at a second orientation to induce a second motion of the phase-change material.

The foregoing features and elements may be combined in various combinations without exclusivity, unless expressly indicated otherwise. These features and elements as well as the operation thereof will become more apparent in light of the following description and the accompanying drawings. It should be understood, however, that the following description and drawings are intended to be illustrative and explanatory in nature and non-limiting.

### BRIEF DESCRIPTION OF THE SEVERAL VIEWS OF THE DRAWINGS

The subject matter is particularly pointed out and distinctly claimed at the conclusion of the specification. The foregoing and other features, and advantages of the present disclosure are apparent from the following detailed description taken in conjunction with the accompanying drawings in which:

FIG. 1A is a schematic diagram of a thermal management system in accordance with an embodiment of the present disclosure;

FIG. 1B is a schematic diagram of another configuration of a thermal management system in accordance with an embodiment of the present disclosure;

FIG. 2A is a schematic illustration of operation of a thermal management system in accordance with an embodiment of the present disclosure, shown in a first state of operation;

FIG. 2B illustrates a second state of operation of the thermal management system of FIG. 2A;

FIG. 3A is a schematic illustration of operation of a thermal management system in accordance with an embodiment of the present disclosure, shown in a first state of operation;

FIG. 3B illustrates a second state of operation of the thermal management system of FIG. 3A;

FIG. 4 is a schematic illustration of another configuration of a thermal management system in accordance with an embodiment of the present disclosure;

FIG. 5 is a schematic illustration of another configuration of a thermal management system in accordance with an embodiment of the present disclosure;

FIG. 6 illustrates a number of different configurations of active particles that may be used with thermal management systems in accordance with embodiments of the present disclosure;

FIG. 7A is a schematic illustration of operation of a thermal management system in accordance with another embodiment of the present disclosure, shown in a first state of operation; and

FIG. 7B illustrates a second state of operation of the thermal management system of FIG. 7A.

### DETAILED DESCRIPTION

As shown and described herein, various features of the disclosure will be presented. Various embodiments will be described and various features may include changes, alterations, modifications, etc. as will be appreciated by those of skill in the art, whether explicitly described or otherwise would be appreciated by those of skill in the art. A more thorough description will now be provided with reference to the accompanying figures. The details shown in the figures are not necessarily to scale, but are shown to aid in understanding the features of the subject technology and for illustrative and explanatory purposes.

A characteristic property of phase-change materials (PCMs) is that PCMs have a latent heat of fusion. This allows PCMs to store a large amount of energy with a low temperature increase. As such, PCMs tend to be a solution to certain challenges in dynamic thermal management. However, another characteristic property of PCMs is that the power density tends to decrease as a transient melt front moves away from a heat source. In operation, PCM used for the transient thermal management can be initially in a solid state. As heat is transferred from the heat source to the PCM, the temperature of the solid PCM increases due to absorption of heat until it starts to melt. The melting (or phase change) occurs when the melting point of the PCM is reached due to heat pickup or heat transfer from the heat source. During the phase change, the PCM temperature will remain relatively constant as heat absorbed is stored as latent heat until all solid portions of the PCM becomes completely liquid. Thus, the total mass correlates to the thermal storage capacity. The thermal resistance (Rₜₕ) of the liquid layer, which determines the power capability of the PCM, is proportional to the melt-front thickness.

In accordance with embodiments of the present disclosure, the heat flux capability of a phase-change thermal management system is improved through forced convection. Advantageously, embodiments of the present disclosure are directed to forced convection that does not use any external mechanical input/mechanism, such as a pump or the like. For example, in accordance with some embodiments, forced convection of a phase-change material/media (PCM) is achieved through the use and manipulation of active particles (e.g., charged particles and/or magnetic particles) and application of electric fields, electric currents, and/or magnetic fields, respective. The implementation of forced convection can eliminate, mitigate, or reduce “vapor-lock” in a liquid-gas phase-change system or “melt-pool” in a solid-liquid phase-change system. For example, in the case of a solid-liquid PCM, as the PCM melts and the liquid interface grows, the thermal resistance of the liquid layer increases. The liquid layer can increase to sufficient size (e.g., distance from the heat source/load) that the remaining solid portion of the PCM may not be able to absorb additional heat to melt the PCM, which can result in the melt-pool issue that can reduce the efficiency and efficacy of such PCM cooling systems. In accordance with embodiments of the present disclosure, PCM systems are provided with a means or mechanism to replace the liquid PCM that is proximate a heat load with solid portions of the PCM, and hence maintain the thermal resistance of the liquid layer at a level to ensure desired thermal management.

In accordance with some embodiments, active particles in the form of charged particles are added or embedded into a phase-change material. The charged particles may be positively and/or negatively charged particles which are urged into motion or caused to move under an applied electric field. That is, application of an electrical field to the phase-change material having embedded charged particles can cause movement of the charged particles, which in turn carry or cause movement of the phase-change material. By applying the electric field, an electrostatic migration driven flow may be induced. Alternatively, an electric field can be used to induce an ionic current to flow between electrodes, and charge carriers can induce flow by dragging liquid PCM molecules. The directed flow, by application of the electric field to the charged particles, will cause movement of the PCM when it is in liquid form since it can no longer sustain any strain. As the liquid portion grows due to heat pickup, the applied electric field will urge the charged particles to induce a flow of the liquid portion of the PCM, thereby moving or carrying the liquid portion away from the heat source, and thus preventing a melt-pool from growing and increasing the distance between the heat source/load and a melt front in the PCM. The reduction of the presence of a melt-pool can retain the thermal load that can be absorbed into the PCM, thereby improving the thermal capacity and/or efficiency of the PCM system.

In accordance with some embodiments, active particles in the form of magnetic particles are added or embedded into a phase-change material. The magnetic particles may be magnetically polarized particles which are urged into motion or caused to move under an applied magnetic field. That is, application of a magnetic field to the phase-change material having embedded magnetic particles can cause movement of the magnetic particles, which in turn carry or cause movement of the phase-change material. By applying the magnetic field, a magnetophoretically driven flow may be induced. The directed flow, by application of the magnetic field to the magnetic particles, will cause movement of the PCM when it is changed from, for example, a solid to a liquid. As the liquid portion grows due to heat pickup, the applied magnetic field will urge the magnetic particles to induce a flow of the liquid portion of the PCM, thereby moving or carrying the liquid portion away from the heat source, and thus preventing a melt-pool from forming. The reduction of the presence of a melt-pool can increase the thermal load that can be absorbed into the PCM, thereby improving the thermal capacity and/or efficiency of the PCM system.

It will be appreciated that combinations of both magnetic and electrically charged active particles may be implemented within PCM systems without departing from the scope of the present disclosure. In such configurations, driving mechanisms for various types of active particles (e.g., charged particles and magnetic particles) may be provided with the PCM assembly, such that both electric and magnetic fields can be generated to induce flows within the phase-change materials.

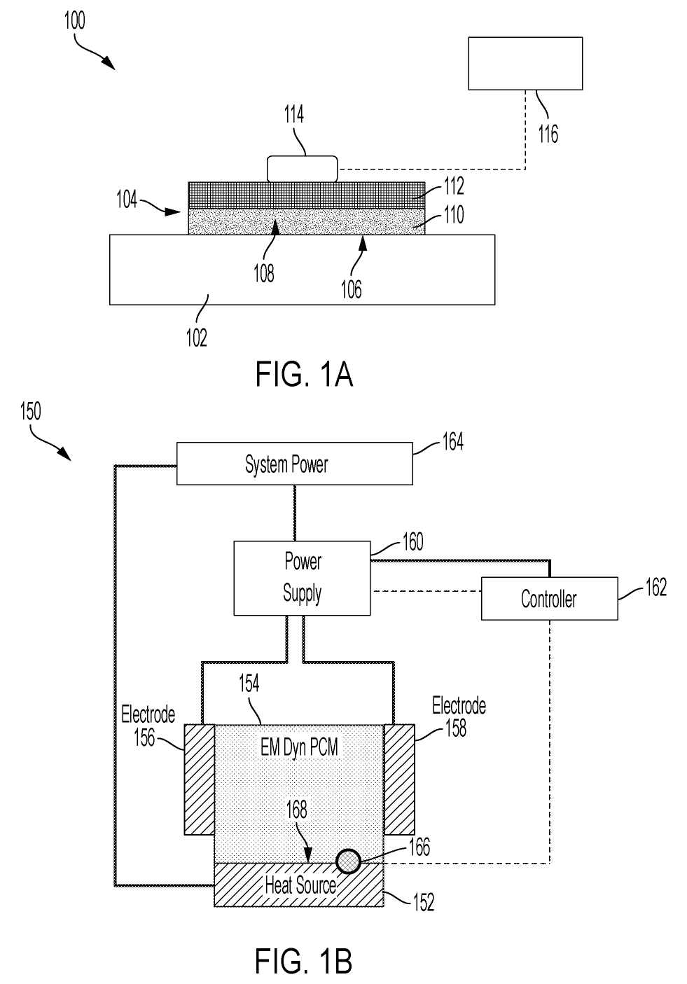

Referring now to FIGS. 1A-1B, schematic illustrations of thermal management systems 100, 150 arranged in accordance with embodiments of the present disclosure is shown. The thermal management systems 100, 150 is arranged to provide cooling or heat removal from a heat load 102, such as an electronic component or the like. The thermal management system 100 is arranged with a phase-change element 104 that is arranged in thermal contact with the heat load 102. That is, there is a thermal interface 106 that is defined between the heat load 102 and the phase-change element 104 that is arranged to allow for thermal heat pickup by the phase-change element 104 from the heat load 102.

The phase-change element 104 is a structural element that contains a phase-change material 108 which may be in different physical states (e.g., solid or liquid; or liquid or gas) depending on heat pickup from the heat load 102. As shown in FIG. 1A, the phase-change material 108 includes a first portion 110 (e.g., liquid portion or gaseous portion) that includes or extends along the thermal interface 106 and a second portion 112 (e.g., solid portion or liquid portion). As the phase-change material 108 picks up heat from the heat load 102, the phase-change material 108 may melt (or evaporate). As additional heat is picked up by the phase-change material 108, more of the phase-change material 108 will change from solid (or liquid) to liquid (or gas).

For simplicity of discussion, reference will be made to a solid-liquid phase-change material, which is solid until heat is picked up from a heat load and the solid material is melted into a liquid material. It will be appreciated by those of skill in the art that liquid starting material may be converted to a gaseous state by application of heat (e.g., boiling, evaporation, etc.). Although reference will be made to a solid that is melted during heat pickup, it will be appreciated that the concept referred to is a phase change from a first material state to a second material state by application of heat, and thus the present disclosure is not intended to be limited to solid-liquid PCM systems. Accordingly, as used herein, the first portion 110 is a movable or mobile portion of the PCM 108 and the second portion 112 is a stationary (or substantially stationary or immobile) portion of the PCM 108.

As the PCM 108 transitions from the first state (e.g., solid) to the second state (e.g., liquid), heat is removed from the heat load 102. In order to ensure that a melt pool does not form of sufficient size to reduce heat pickup by the PCM 108, the thermal management system 100 includes a field generator 114. The field generator 114 is configured to be provided with commands and/or power from a controller 116 that is operably connected to the field generator 114 (e.g., wired or wirelessly). In some embodiments, the controller 116 may be configured as multiple distinct elements, such as a power source (e.g., battery, generator, motor, etc.) and a controller (e.g., integrated circuit, processor, etc.). In still other embodiments, a control element may be omitted, and in such configurations, the field generator 114 may be continuously supplied with power and induce a field such that when the material of the PCM 108 changes from the state of the second portion 112 to the state of the first portion 110, the first portion 110 will be induced to move due to application of the field from the field generator 114. Accordingly, the second portion 112 may be able to pick up heat and fill the space that is created by the first portion 110 that is moved due to application of the field by the field generator 114. Accordingly, the overall efficiency and heat pickup can be improved by ensuring that melt pools (or vapor locks) do not occur.

FIG. 1B illustrates an alternative system configuration of a thermal management system 150 for cooling a heat load 152 that is arranged with a phase-change element 154 arranged in thermal contact with the heat load 152. The phase-change element 154 is a structural element that contains a phase-change material which may be in different physical states (e.g., solid or liquid; or liquid or gas) depending on heat pickup from the heat load 152. As the phase-change element 154 picks up heat from the heat load 152, the phase-change material may melt (or evaporate), as described above. Similar to the thermal management system 100, the thermal management system 150 includes a field generator in the form of a first electrode 156 and a second electrode 158. The electrodes 156, 158 are provided power from a power supply 160 which is configured to be controlled by a controller 162. The power supply 160 may receive power from a system power element 164, which may also be electrically coupled to the heat load 152 and may provide electrical power to the heat load 152 (e.g., an electronics component).

A thermal sensor 166, such as a thermocouple, may be installed to detect and/or monitor the conditions at the interface 168 of the heat load 152 and the phase-change element 154. The controller 162, which may receive power from the power supply 160, is configured to assess data (dashed lines) from the thermal sensor 166 (e.g. temperature) and sends signals (dashed lines) to the power supply 160. The power supply 160 is configured to deliver power to the controller 162 and receive signals (dashed lines) from the controller 162 indicating whether to deliver power (solid lines) to the electrodes 156, 158 of the field generator and in what mode (e.g., melting mode or freezing mode). The power supply 160 delivers (or does not deliver) power (solid lines) to the electrodes 156, 158 (or electromagnetic coils) to induce an electric (or magnetic field).

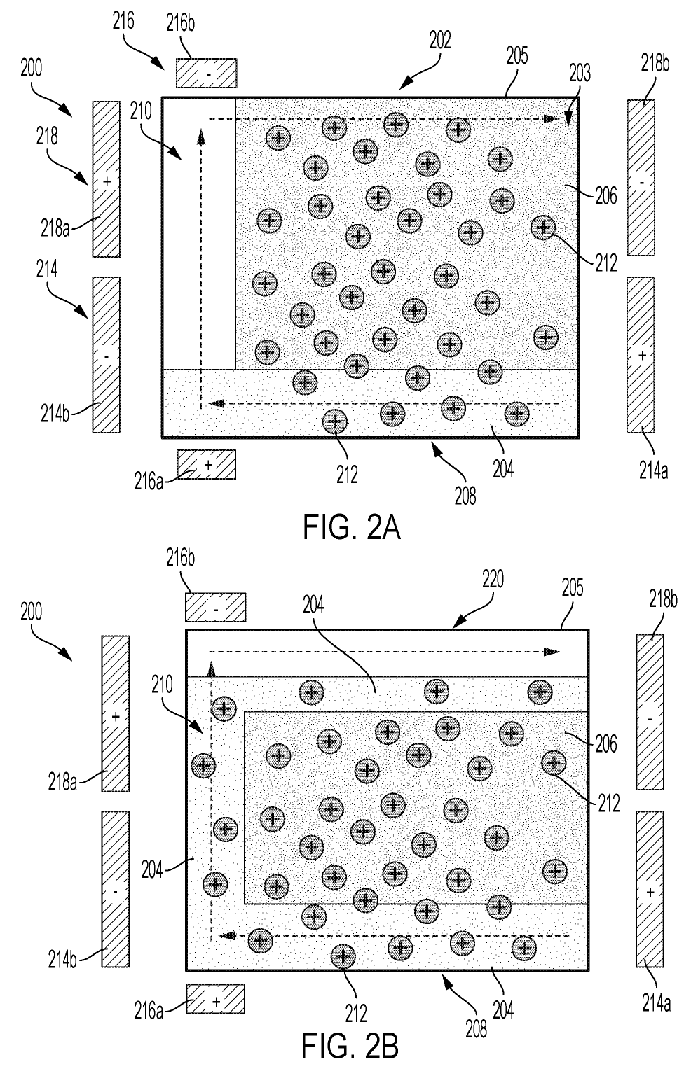

Referring now to FIGS. 2A-2B, schematic illustrations of a thermal management system 200 in accordance with an embodiment of the present disclosure are shown. The thermal management system 200 may be configured similar to that shown in FIGS. 1A-1B, although certain features are not illustrated for clarity and simplicity of explanation. FIGS. 2A-2B illustrate a phase-change element 202 having a phase-change material 203 that includes a first portion 204 and a second portion 206 housed within a housing 205. The illustrations of FIGS. 2A-2B illustrate the phase-change material 203 in a two-state configuration, defining the first portion 204 and the second portion 206 within the housing 205. The two-state arrangement exists when heat is picked up by the phase-change material 203 and a portion of the phase-change material 203 changes state, such as from a solid to a liquid (or liquid to a gas). When no heat is present, the housing 205 of the phase-change element 202 may be filled with all solid material (e.g., second portion 206). As heat is picked up, the phase-change material 203 will transition into a two-phase state, with the first portion 204 forming along a thermal interface 208 of the housing 203 that is arranged in thermal contact with a heat load.

The phase-change element 202 is provided with a void space 210 that is a void or channel within the housing 203. The void space 210 extends from the thermal interface 208 in a direction normal to the thermal interface 208 (i.e., in a direction away from the thermal interface 208). In some embodiments, the void space 210 may be a structurally defined channel, conduit, path, or the like that is formed within or as part of the housing 205. In other embodiments, the void space 210 may be defined by a volume of the interior of the housing 205 that is not occupied by the phase-change material 203 when not in use (e.g., when the phase-change material 203 is uniform and solid). The void space 210 may be selected to be of sufficient volume to accommodate a change in phase of the phase-change material 203 and permit a flow of material, as described herein. As heat is picked up by the phase-change material 203, a portion of the phase-change material 203 will change state (e.g., melt from a solid to a liquid) to form and define the first portion 204 which is separate from the second portion 206 in terms of physical state. As additional heat is picked up within the first portion 204, the first portion 204 of the phase-change material 203 will grow size.

Without the inclusion of the void space 210 and/or a motive force, a melt-pool may form where the first portion 204 of the phase-change material 203 along the thermal interface 208 melts but does not move. This pooling of the first portion 204 of the phase-change material can form or define a thermal resistance that prevents the phase-change material 203 that is farther from the thermal interface 208 from picking up heat and melting. Accordingly, losses may occur as a limit may be reached where further heat absorption at near constant temperature becomes infeasible.

To ensure efficient heat pickup, the thermal management system 200 includes a mechanism for moving the phase-change material 203 of the first portion 204 away from the thermal interface 208. By moving the first portion 204 away from the thermal interface 208, the second portion 206 of the phase-change material 203 may enter the space that was previously occupied by the first portion 204. Accordingly, the second portion 206 may pick up heat and melt, adding to the first portion 204. As such, a cycle or flow of the phase-change material 203 may be generated. As the first portion 204 of the phase-change material 203 is moved away from the thermal interface 208, the material may cool and start to resolidify, and then mix or be added to the second portion 206, before melting and joining the first portion 204 again. The cycle of the phase-change material 203 of the phase-change element 202 is schematically illustrated by the dashed line arrows shown in FIGS. 2A-2B.

In this illustrative configuration, the phase-change material 203 of the phase-change element 202 is embedded with or provided with embedded active particles 212. In this configuration, the active particles 212 are electrically charged particles. The active particles 212 are selected to have a specific charge (e.g., positive charge or negative charge), such that application of an electric field to the active particles 212 induces the active particles 212 to move in a predetermined manner. The movement of the phase-change material 203 (in a mobile form such as liquid state), in this embodiment, is induced by application of an electric field (or electromagnetic field) from one or more field generators 214, 216, 218. As illustratively shown in this configuration, the active particles 212 are selected with a positive charge (+). Accordingly, a positively charged field will repel the active particles 212 and a negatively charged field will attract the active particles 212. The electric field generated by electrodes of the field generators 214, 216, 218 may be relatively low (e.g., less than 10V applied potential). Further, in accordance with some embodiments, if the generated field may potentially interfere with operation of the heat load component (e.g., electronic device), electromagnetic shielding may be implemented to ensure that the generated electric field(s) impact only the PCM and do not interfere with operation of a heat load operation (e.g., electronic device).

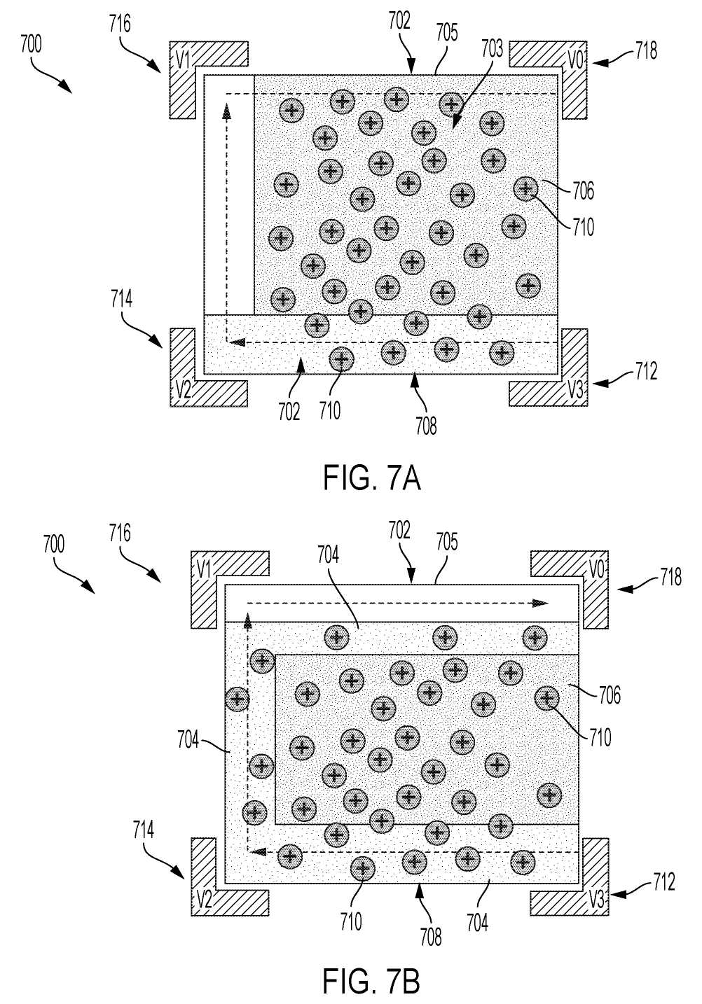

As shown, in this illustrative configuration, the thermal management system 200 includes three field generators 214, 216, 218. A first field generator 214 includes a positive electrode 214a arranged opposite from a negative electrode 214b, with the positive and negative electrodes 214a, 214b arranged on opposite sides of the housing 205. When an electric field is induced by the electrodes 214a, 214b of the first field generator 214, the positively charged-active particles 212 will be urged to move away from the positive electrode 214a and toward the negative electrode 214b (i.e., in a direction to the left on the page of FIGS. 2A-2B, and as indicated by the dashed arrow line). As such, when the first portion 204 of the phase-change material 203 changes state from solid to liquid, the liquid portion (first portion 204) will be caused to move with the moving active particles 212. Alternatively, in other configurations, the electrodes may be arranged on or at corners of the housing of the phase-change element, as shown and described with respect to FIG. 7.

As the phase-change material 203 melts near the interface 214, the first portion 204 is urged toward the negative electrode 214b of the first field generator 214, the phase-change material 203 will occupy the volume left by the transported liquid PCM. To move the melted phase-change material 203 (first portion 204) away from the thermal interface 208, a second field generator 216 is arranged to urge the active particles 212, and the phase-change material 203 of the first portion 204, to travel in a direction away from the thermal interface 208. The second field generator 216 includes a positive electrode 216a arranged proximate the thermal interface 208, or arranged to generate a positive electric field proximate the thermal interface 208. Opposite the positive electrode 216a, relative to the housing 205, is a negative electrode 216b of the second field generator 216. Accordingly, the positively charged-active particles 212 will be caused to move away from the positive electrode 216a and the thermal interface 208 and toward the negative electrode 216b of the second field generator 216. In this configuration, the second field generator 216 is arranged relative to or aligned with the void space 210 to cause movement of the active particles 212 and the phase-change material 203 to flow through the void space 210, thus making space for additional liquid material to fill the regions from where the phase-change material 203 is removed.

To continue the cycle or flow loop, the thermal management system 200 includes a third field generator 218, which includes a positive electrode 218a and a negative electrode 218b. The third field generator 218 is arranged substantially parallel with the first field generator 214, but in an opposite direction or orientation. That is, the third field generator 218 is positioned and arranged to cause the active particles 212 to continue along a backside 220 of the housing 205, which is opposite the thermal interface 208. The backside 220 may be a region of relative cool temperatures, as compared to the thermal interface 208, and thus the phase-change material 203 may cool. The arrangement of the field generators 214, 216, 218 are selected to induce a cycle or flow circuit that causes warmed and melted phase-change material 203 (e.g., first portion 204) to be carried away from the thermal interface 208 such that cooler portions of the phase change material 203 (e.g., second portion 206) are free to interact with the thermal interface 208 and thus pick up heat from a heat load that is arranged in thermal contact with the thermal interface 208.

The electric fields induced by the field generators 214, 216, 218 may be controlled by an external controller or may be powered on and present any time the thermal management system 200 is in use. In some embodiments, a changing electric field may be induced, rather than a static positive-negative field. However, it will be appreciated that even with a variable or changing electric field, the application thereof is to cause a fluid flow, fluid cycle, or fluid circuit, such that a melt pool does not form along the thermal interface 208. In some configurations, the ability to change the electric field generated by the field generators 214, 216, 218 can allow for control of shaping of the phase-change material 203 upon shutdown and re-freezing, to ensure that the void space 210 is present for the next time the system is initiated and turned on.

In accordance with some embodiments, the electric field systems described with respect to FIGS. 2A-2B may be used with solid-liquid phase change materials to prevent melt pools from forming. Furthermore, in other embodiments, the electric field systems may be used in liquid-gas phase change systems to prevent vapor-lock or the like. In such configurations, the induced fields may cause the mixture of liquid and vapor to be moved in a circuit, rather than moving the liquid portion relative to a solid portion, as is the case for solid-liquid phase change systems. In accordance with embodiments of the present disclosure, the solids (solid-liquid system) may be, for example, and without limitation, paraffins, ice, low-melting metals, etc., and the liquids (liquid-gas systems) may be water, alcohols, refrigerants, or the like. The embedded or included active particles may be glass beads, plastic beads, specifically selected ionic molecules, polymers, or the like. Addition to the PCM of redox couples such as ferrocene/ferrocenium or ferro/ferricyanide can enable current to travel between electrodes and induce ionic current with the charged species.

The configuration of FIGS. 2A-2B is based on use of embedded charged active particles suspended within a phase-change material. By applying a directed or oriented electric field, the charged active particles can be caused to move (e.g., away from same polarity electrode, toward opposite polarity electrode, with or against ionic current). As the charged active particles are moved, the motion of the charged active particles will induce a flow or cause movement of the phase-change material, particularly in the mobile state (e.g., liquid). In alternative configurations, or in combination with electric field operation, embodiment of the present disclosure include magnetically induced flow of phase-change materials.

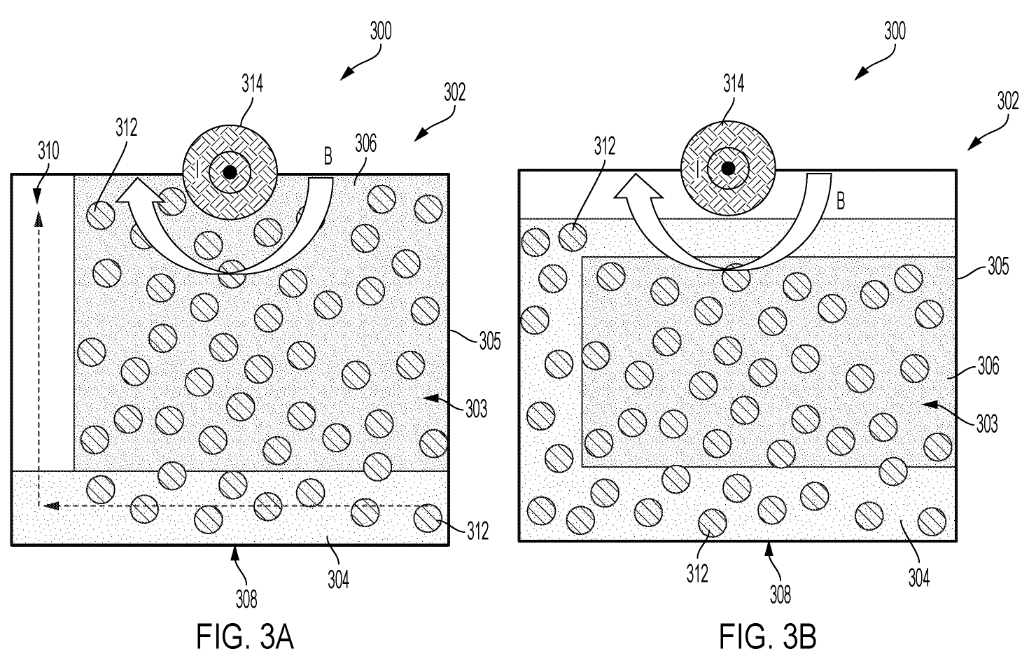

For example, referring now schematic illustrations of a thermal management system 300 in accordance with an embodiment of the present disclosure is shown. The thermal management system 300 may be configured similar to that shown in FIGS. 1A-1B, although certain features are not illustrated for clarity and simplicity of explanation. FIGS. 3A-3B illustrate a phase-change element 302 having a phase-change material 303 that includes a first portion 304 and a second portion 306 housed within a housing 305. The illustrations of FIGS. 3A-3B illustrate the phase-change material 303 in a two-state configuration, defining the first portion 304 and the second portion 306 within the housing 305. The two-state arrangement exists when heat is picked up by the phase-change material 303 along a thermal interface 308 with a heat load. During heat pickup, a portion of the phase-change material 303 changes state, such as from a solid to a liquid (or liquid to a gas). When no heat is present, the housing 305 of the phase-change element 302 may be filled with all solid material (e.g., second portion 306). As heat is picked up, the phase-change material 303 will transition into a two-phase state, with the first portion 304 forming along the thermal interface 308 of the housing 303 that is arranged in thermal contact with the heat load.

The phase-change element 302 defines a void space 310 within the housing 303, similar to that shown and described above. The phase-change material 303 of this configuration is configured with embedded or suspended active particles 312, which may be magnetic particles. By applying a magnetic field to the phase-change material 303, with the embedded active particles 312, a flow may be induced, similar to that shown and described above. For example, as heat is picked up by the phase-change material 303, the first portion 304 of mobile material may be urged into motion by applying a magnetic field that causes the active particles 312 to move, which thereby carries or forces the phase-change material 303 to move in a cycle or circuit. The magnetic field may be induced by a field generator 314, which in this configuration generates a magnetic field, rather than an electric field. The active particles 312 may be formed from, for example and without limitation, ferromagnetic or paramagnetic materials. The active particles 312, when in the melt phase (first portion 304) experience magnetohydrodynamic torque and force due to the magnetic field that is generated at the field generator 314 and mutual interactions in the liquid phase and hydrodynamic interactions with bounded domain. Upon rotation and translation, the magnetic active particles will displace and transport the first portion 304 of the phase-change material 303.

It will be appreciated that the configuration and number of magnets, coils, and/or other field generators may be varied or selected for specific application. By arranging a desired number and orientation of field generators, the direction and layout of the magnetic field may be customized to achieve design-specific application and can be customized based on, for example, an orientation of an applied heat source and/or a desired direction for displacement of the melt. Such adjustments and/or customization are not limited to the magnetic configuration, but may also be implemented through selecting the number, placement, strength, and/or other characteristics of the electrodes of the electric field generator systems (e.g., FIGS. 2A-2B).

In accordance with embodiments of the present disclosure active particles are embedded into a phase-change material. The active particles may be electrically charged active particles (e.g., FIGS. 2A-2B) or magnetic active particles (e.g., FIGS. 3A-3B). The active particles are embedded within or suspended within at least a part of the phase-change material. When heat is applied to the phase-change material, and a phase change occurs, the application of a carrier field (e.g., electric field, magnetic field, electromagnetic field) will induce movement of the active particles and thereby induce movement of the phase-change material. That is, as the active particles are caused to move by application of the field, the active particles will displace the phase-change material, and transport or move the phase-change material. Accordingly, no pumping or other types of mechanical solutions are necessary to cause movement and a flow circuit to be defined within a housing of a phase-change element. Further, because no pumps or direct interaction with the phase-change material is necessary to induce the movement, fewer components and points of failure may be present as compared to a system that requires a motive driver for the fluid.

In accordance with embodiments of the present disclosure, the active particles may be selected or configured to achieve a desired flow state of the phase-change material when subject to the applied fields from the field generators. For example, different shapes of active particles can be embedded or suspended in the melt-phase of the phase-change material based on design requirements and/or other considerations. Additionally, the density, concentration, size, material selection, and other features and characteristics of the active particles may be based on a specific application and use (e.g., based on experienced/expected temperatures, type of phase-change material, desired flow characteristics, etc.). As used herein, a density of the active particles is a gravimetric density and a concentration of active particles is a volumetric or molecular fraction.

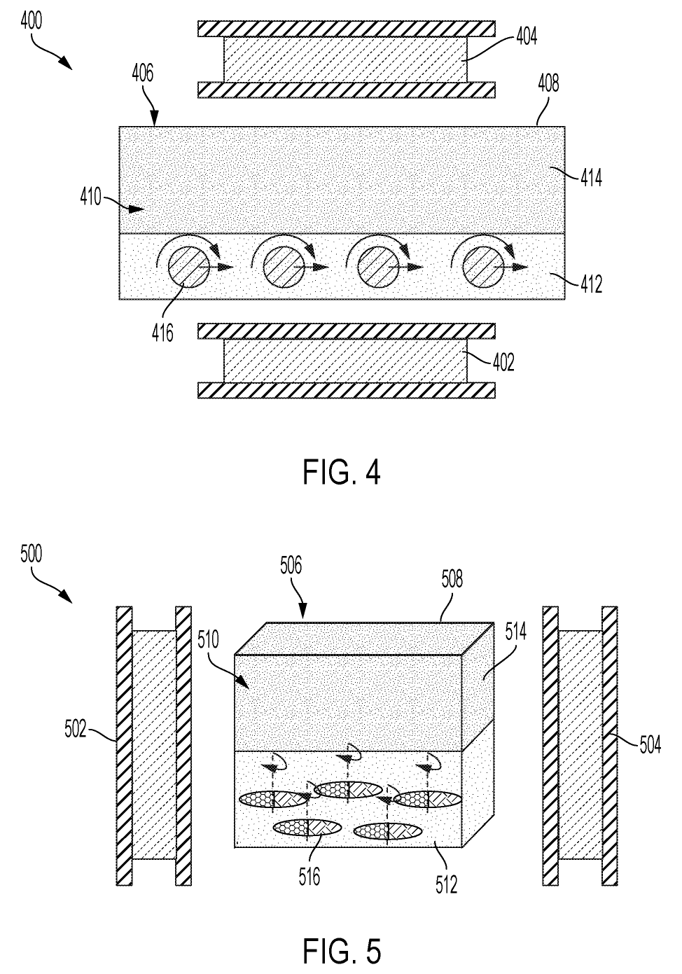

Referring now to FIG. 4, a schematic illustration of a portion of a thermal management system 400 in accordance with an embodiment of the present disclosure is shown. The thermal management system 400 may be similar to that shown and described above. The thermal management system 400 includes a first field generator 402 and a second field generator 404 arranged on opposite sides of a phase-change element 406. The phase-change element 406 includes a housing 408 with a phase-change material 410 contained therein. The phase-change material 410, during use, may have a first portion 412 (e.g., liquid) and a second portion 414 (e.g., solid). Embedded within the phase-change material 410 are a number of active particles 416, which may be magnetic particles. The field generators 402, 404 may be configured to generate an alternating magnetic field. The active particles 416 in the melt phase (first portion 412; liquid state of the phase-change material 410) experience magnetohydrodynamic torque and force due to external alternating magnetic field applied by the field generators 402, 404, mutual interactions between the active particles 416 within the first portion 412, and hydrodynamic interactions with the bounded domain. Upon rotation and translation of the active particles 416, the phase-change material 410 in the first portion 412 will be displaced and transported or moved. The displacement of the phase-change material 410 in the first portion 412 allows for additional phase-change material 410 from the second portion 414 to be exposed to a heat load, and thus a fluid circuit or flow may be generated. In the configuration of FIG. 4, the active particles 416 are sedimented and rotate and translate in the melt phase (first portion 412) upon experiencing alternating magnetic field from external magnetic coils (field generators 402, 404). The melt phase (first portion 412) is displaced due to hydrodynamic force exerted by the moving active particles 416.

Referring now to FIG. 5, a schematic illustration of a portion of a thermal management system 500 in accordance with an embodiment of the present disclosure is shown. The thermal management system 500 may be similar to that shown and described above. The thermal management system 500 includes a first field generator 502 and a second field generator 504 arranged on opposite sides of a phase-change element 506. The phase-change element 506 includes a housing 508 with a phase-change material 510 contained therein. The phase-change material 510, during use, may have a first portion 512 (e.g., liquid) and a second portion 514 (e.g., solid). Embedded within the phase- change material 510 are a number of active particles 516, which may be magnetic particles. The field generators 502, 504 may be configured to generate an alternating magnetic field. The active particles 516 in the melt phase (first portion 512; liquid state of the phase-change material 510) experience magnetohydrodynamic torque and force due to external alternating magnetic field applied by the field generators 502, 504, mutual interactions between the active particles 516 within the first portion 512, and hydrodynamic interactions with the bounded domain. Upon rotation and translation of the active particles 516, the phase-change material 510 in the first portion 512 will be displaced and transported or moved. The displacement of the phase-change material 510 in the first portion 512 allows for additional phase-change material 510 from the second portion 514 to be exposed to a heat load, and thus a fluid circuit or flow may be generated. In the configuration of FIG. 5, a suspension of partially sputter-coated ferromagnetic particles (active particles 516) are induced to rotate and stir and displace the melt-phase (first portion 512) allowing for additional phase-change material 510 to backfill and replace the displaced liquid portion of the phase-change material 510.

In accordance with some embodiments, the magnetic field systems described with respect to FIGS. 3A-3B, 4, and 5 may be used with solid-liquid phase-change materials to prevent melt pools from forming. Furthermore, in other embodiments, the magnetic field systems may be used in liquid-gas phase-change systems to prevent vapor-lock or the like. In such configurations, the induced fields may cause the mixture of liquid and gas (or vapor) to be moved in a circuit, rather than moving the liquid portion relative to a solid portion, as is the case for solid-liquid phase-change systems. In accordance with embodiments of the present disclosure, the embedded or included magnetic particles (i.e., active particles) may be formed from various magnetic materials (e.g., Ferro/Paramagnetic materials: Fe₃O₄, Fe₇S₈, FeTiO₃, FeCrO₃, Fe₂O₃) and/or magnetic-coated materials (e.g., sputter-coated glass beads or polymer beads). The magnetic systems may be customized or adjusted based on placement and/or orientation of wires and/or solenoids used to induce the magnetic fields and thus control of the magnetic field may be provided. In some configurations, the polarity of the magnetic fields may be controlled to control a shape of the phase-change material upon refreezing or solidification. In accordance with some non-limiting embodiments, the magnetic active particles can be formed from ferromagnetic particles such as nickel. In some other embodiments, ferromagnetic material(s), such as nickel, can be sputter-coated on glass beads (SiO₂) or polymer beads with a suitable passivation layer such as gold (Au).

As noted above, the density of active particles can be varied to ensure a desired flow or induced flow of the phase-change material. For example, in some configurations of a magnetic application, the density of active particles may be such that the active particles can sediment in the melt phase to undergo translation upon rotation (e.g., FIG. 4). In other configurations, the density of the active particles can be matched with the density of melt phase such that it creates a homogenous suspension (e.g., FIG. 5). The features or characteristics of the thermal management systems described herein may be adjusted based on the specific application, materials used, and in view of other considerations. For example, and without limitation, the frequency (e.g., <1 – 100s Hz) and magnitude of a rotating magnetic field (e.g., 1-10s mT, depending on hydrodynamic friction to initiate and sustain the motion), and size of the active particles (e.g., scalable, micron to mm scale) may each be set based on a specific implementation, application, or other design-consideration.

In accordance with various embodiments, whether using an electric field system or a magnetic field system, the active particles can be provided in variety of shapes, sizes, materials, densities, particle density, and the like. For example, in some configurations, the active particles may be spherical, cylindrical, and ellipsoid beads that are mixed within the phase-change material (e.g., embedded, deposited, suspended, etc.). In accordance with some embodiments, microfabrication techniques can be used for batch manufacturing of microparticles with complex geometries, such as impeller configurations, which can provide for improved and optimized mixing and transport of the phase-change material.

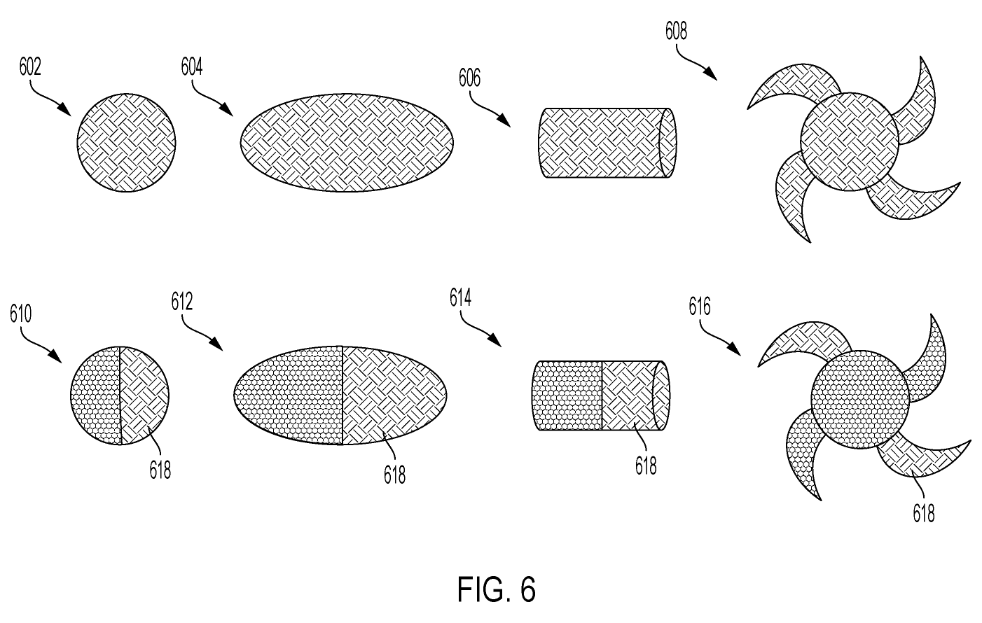

For example, referring now to FIG. 6, schematic illustrations of different active particle geometries and configurations that may be used with embodiments of the present disclosure are shown. As shown, a first example active particle 602 may be a round or spherical and made of a magnetic material (e.g., ferromagnetic). A second example active particle 604 is another magnetic material active particle , but arranged in an oval or ovoid shape. A third example active particle 606 is arranged as a cylinder, and a fourth example active particle 608 is arranged as a pinwheel or impeller. Each of the third and fourth example active particles 606, 608 may be formed from magnetic materials. The example magnetic active particles 602, 604, 606, 608 may be formed from magnetic materials or ferromagnetic materials, including, without limitation, nickel. A second set of example active particles 610, 612, 614, 616 are shown, having substantially similar geometries, but each of these active particles 610, 612, 614, 616 is at least partially coated with a magnetic (or ferromagnetic) coating 618. The active particles 610, 612, 614, 616 may be formed of a non-magnetic material, such as glass or the like (e.g., SiO₂) and/or polymer beads with a suitable passivation layer, such as gold (Au). In accordance with some non-limiting embodiments, the coatings may be applied, for example, by sputter-coating techniques. The active particles can be provided in variety of shapes and/or geometries, including spherical, cylindrical, and ellipsoid beads. Microfabrication techniques can be used for batch manufacturing of microparticles with complex geometries, such as impeller and/or pinwheel, for improved and optimized mixing and transport of liquid phase. The active particles 602-616 may experience magnetohydrodynamic torque when exposed to an external oscillating magnetic field, and thus may be caused to drive a flow of a phase-change material, as described above.

Referring now to FIGS. 7A-7B, schematic illustrations of a thermal management system 700 in accordance with an embodiment of the present disclosure are shown. The thermal management system 700 may be configured similar to that shown in FIGS. 2A-2B. FIGS. 7A-7B illustrate a phase-change element 702 having a phase-change material 703 that includes a first portion 704 and a second portion 706 housed within a housing 705. The phase-change material 703 exists in two-states when heat is picked up by the phase-change material 703 and a portion of the phase-change material 703 changes state. In operation, heat may be picked up, along a thermal interface 708 of the housing 705 that is arranged in thermal contact with a heat load.

Similar to the above described embodiments, the phase-change material 703 of the phase-change element 702 is embedded with or provided with embedded active particles 710. In this configuration, the active particles 710 are electrically charged particles, similar to the embodiment shown and described with respect to FIGS. 2A-2B. The active particles 710 are selected to have a specific charge (e.g., positive charge or negative charge), such that application of an electric field to the active particles 710 induces the active particles 710 to move in a predetermined manner. The movement of the phase-change material 703 (in a mobile form such as liquid state), in this embodiment, is induced by application of an electric field (or electromagnetic field) from one or more field generators 712, 714, 716, 718. In accordance with some embodiments, the electric field generated by electrodes of the field generators 712, 714, 716, 718 may be relatively low (e.g., less than 10V applied potential).

As shown, in this illustrative configuration, the thermal management system 700 includes four field generators 712, 714, 716, 718. A first field generator 712 may be arranged at a first corner of the housing 705 and assigned or operated at a predetermined or specific voltage first V3. The other field generators 714, 716, 718 are arranged in a clockwise arrangement about the corners of the housing 705. The second field generator 714 may be assigned or operated at a predetermined or specific second voltage V2, the third field generator 716 has a respective third voltage V1, and the fourth field generator has a respective fourth voltage V0. The voltages V3, V2, V1, V0 may be set to be relative to each other to induce a flow of the active particles 710 and the first portion 704 (e.g., liquid state) of the phase-change material 703. In accordance with a non-limiting example, the voltages V3, V2, V1, V0 may be assigned with a relationship of V3>V2>V1>V0>0. In other configurations, and without limitation and for example only, the relationship may be: V3<V2<V1<V0<0; V3<V2<0<V1<V0; or the like, as will be appreciated by those of skill in the art. The selection of voltages V3, V2, V1, V0 may be such that the potential induces a directional flow (e.g., clockwise) to allow for removal of liquid phase-change material from the interface 708 and allow for additional phase-change material to absorb heat from a heat load at the interface 708.

Although shown and described above with specific dedicated, purpose orientated field generators arranged about a phase-change element, such field generators are not required for certain embodiments of the present disclosure. For example, if the phase-change elements of the present disclosure, having embedded or suspended active particles within a phase-change material, are arranged relative to a component that generates a field, additional or dedicated field generators may not be required. For example, and without limitation, in some configurations and applications, the device that defines the heat load may also generate an electric or magnetic field. In such instances, the field generated by the heat load may be sufficient to induce the movement of the active particles and thus improve thermal management without the need for separate field generators. In still other embodiments, the field may be generated by a remote and unrelated component or system. In such configurations, the phase-change element may be positioned on or in thermal contact with a heat load and relative to another component that generates a field (e.g., electric and/or magnetic). This local field may induce the movement of the phase-change material via the active particles, as described in the present disclosure. Accordingly, it will be appreciated that the thermal management systems of the present disclosure do not necessarily require a specific or dedicated field generator(s).

Advantageously, embodiments described herein provide for improved cooling schemes for heat loads and particularly for implementation of use of phase-change materials for cooling schemes. Embodiments of the present disclosure provide for improved cooling and reduces the opportunity for “vapor-lock” (in a liquid-gas phase-change system) or “melt-pool” (in a solid-liquid phase-change system) to form. Furthermore, advantageously, embodiments of the present disclosure provide for passive flow dynamic control to move heated phase-change element material away from a heat source and to allow for additional phase-change material to move into place and absorb additional heat from a heat load.

Embodiments of the present disclosure may provide for reductions in thermal resistance experienced in PCM cooling systems. As the PCM melts and the liquid interface grows, the thermal resistance of the liquid layer increases. Embodiments of the present disclosure provide a means to replace the liquid PCM with solid PCM, and thus maintain the thermal resistance of the liquid layer at a certain level. Furthermore advantageously, embodiments of the present disclosure can increase the reliability of electronic devices by using the dynamic PCM described herein because the phase change process can reduce sudden temperature spikes experienced by components that are cooled by the systems. Therefore, the devices are maintained at an equalized temperature.

The use of the terms "a", "an", "the", and similar references in the context of description (especially in the context of the following claims) are to be construed to cover both the singular and the plural, unless otherwise indicated herein or specifically contradicted by context. The modifier "about" used in connection with a quantity is inclusive of the stated value and has the meaning dictated by the context (e.g., it includes the degree of error associated with measurement of the particular quantity). All ranges disclosed herein are inclusive of the endpoints, and the endpoints are independently combinable with each other.

While the present disclosure has been described in detail in connection with only a limited number of embodiments, it should be readily understood that the present disclosure is not limited to such disclosed embodiments. Rather, the present disclosure can be modified to incorporate any number of variations, alterations, substitutions, combinations, sub-combinations, or equivalent arrangements not heretofore described, but which are commensurate with the scope of the present disclosure. Additionally, while various embodiments of the present disclosure have been described, it is to be understood that aspects of the present disclosure may include only some of the described embodiments. Accordingly, the present disclosure is not to be seen as limited by the foregoing description, but is only limited by the scope of the appended claims.

What is claimed is:

1. A thermal management system comprising:
a phase-change element comprising a phase-change material configured to change in phase state as the phase-change material absorbs heat; and
a plurality of active particles arranged within the phase-change material, the plurality of active particles configured to induce a motion of the phase-change material when subjected to an applied electromagnetic field.

2. The thermal management system of claim 1, further comprising a field generator arranged in proximity to the phase-change element and configured to selectively apply an electromagnetic field to the phase-change element and induce motion of the plurality of active particles.

3. The thermal management system of claim 2, further comprising a controller arranged to control operation of the field generator.

4. The thermal management system of claim 3, further comprising a sensor arranged to monitor a thermal condition at an interface between the phase-change element and a heat load, wherein the controller is configured to cause the field generator to generate the field in response to the thermal condition at the interface.

5. The thermal management system of claim 1, further comprising a heat load.

6. The thermal management system of claim 1, wherein the plurality of active particles comprise charged particles.

7. The thermal management system of claim 6, further comprising a field generator arranged proximate the phase-change element and configured to generate an electric field.

8. The thermal management system of claim 7, wherein the field generator comprises a first electrode arranged on a first side of the phase-change element and a second electrode arranged on a second side of the phase-change element opposite the first electrode.

9. The thermal management system of claim 7, wherein the field generator comprises a first electrode pair arranged to generate a first field in a first orientation and a second electrode pair arranged to generate a second field in a second orientation that is different from the first orientation.

10. The thermal management system of claim 1, wherein the plurality of active particles comprise magnetic particles.

11. The thermal management system of claim 10, further comprising a field generator arranged proximate the phase-change element and configured to generate a magnetic field.

12. The thermal management system of claim 10, wherein the plurality of active particles comprise non-magnetic beads coated with a magnetic material.

13. The thermal management system of claim 1, wherein the phase-change element comprises a housing, wherein the phase-change materials is contained within the housing and the housing further defines a void space defining a path for flow of the phase-change material to travel during application of the applied electromagnetic field.

14. The thermal management system of claim 1, wherein the plurality of active particles are fixed in position within the phase-change element, and application of the applied electromagnetic field to the plurality of active particles causes the plurality of active particles to rotate in place to induce a flow of the phase-change material.

15. The thermal management system of claim 1, wherein the plurality of active particles are embedded within the phase-change material and application of the applied electromagnetic field induces the plurality of active particles to move within the phase-change element and cause a flow of phase-change material.

16. A method of removing heat from a heat load, the method comprising:
arranging a phase-change element in thermal contact with a heat load, wherein the phase-change element comprises a phase-change material having a plurality of active particles arranged within the phase-change material, the plurality of active particles configured to induce a motion of the phase-change material when subjected to an applied electromagnetic field; and
applying an electromagnetic field to the phase-change element to induce a motion of the plurality of active particles and cause motion of the phase-change material.

17. The method of claim 16, wherein the electromagnetic field is an applied magnetic field.

18. The method of claim 16, wherein the electromagnetic field is an applied electric field.

19. The method of claim 16, further comprising monitoring a thermal condition at an interface between the phase-change element and the heat load and applying the field in response to the thermal condition.

20. The method of claim 16, wherein applying the field comprises applying a first field at a first orientation to induce a first motion of the phase-change material and applying a second field at a second orientation to induce a second motion of the phase-change material.
